(19) United States
(12) Patent Application Publication
(10) Pub. No.: US 2021/0040960 A1
(43) Pub. Date: Feb. 11, 2021

(54) FAN FIXING STRUCTURE

(71) Applicant: HONGFUJIN PRECISION ELECTRONICS(TIANJIN)CO.,LTD., Tianjin (CN)

(72) Inventors: TUNG-HO SHIH, New Taipei (TW); YAO-CHIH LIU, New Taipei (TW)

(21) Appl. No.: 16/573,178

(22) Filed: Sep. 17, 2019

(30) Foreign Application Priority Data
Aug. 8, 2019 (CN) 201910731254.3

(51) Int. Cl. F04D 29/60; F04D 25/16; F04D 29/70

(52) U.S. Cl. CPC F04D 29/601; F04D 25/166; F05B 2260/30; F05B 2240/91; F04D 29/703

(57) ABSTRACT

A fan fixing structure includes a mounting plate, a fixing frame, and a collar. The fixing frame is mounted to a fan. The fixing frame defines a latching hole. The collar is received in the latching hole. The collar defines a latching slot. An edge of the fixing frame is latched in the latching slot. The mounting plate includes a positioning post configured to protrude through the collar. The fixing frame mounts the fan to the mounting plate.

### FIELD

The subject matter herein generally relates to fan fixing structures, and more particularly to a fan fixing structure for fixing a fan in a chassis for dissipating heat.

### BACKGROUND

Generally, fans for heat dissipation are fixed in place. If multiple fans are installed side-by-side, each fan is set in a preset position. However, a position of a component which requires heat dissipation may not correspond in position with the fan.

### BRIEF DESCRIPTION OF THE DRAWINGS

Implementations of the present disclosure will now be described, by way of embodiments, with reference to the attached figures.

FIG. 1 is an assembled, isometric view of an embodiment of a fan fixing structure.

FIG. 2 is a partial exploded view of the fan fixing structure in FIG. 1.

FIG. 3 is similar to FIG. 1, but showing the fan fixing structure in another configuration.

FIG. 4 is a diagram showing an embodiment of a positioning post of the fan fixing structure.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

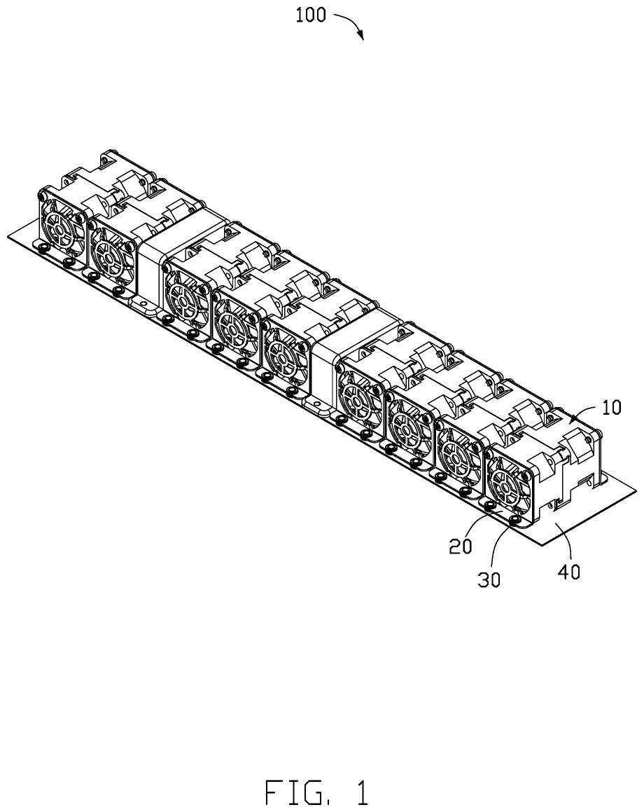

FIG. 1 shows an embodiment of a fan fixing structure 100 for fixing a fan 10 in a chassis (not shown). The fan 10 dissipates heat of electronic components in the chassis (not shown).

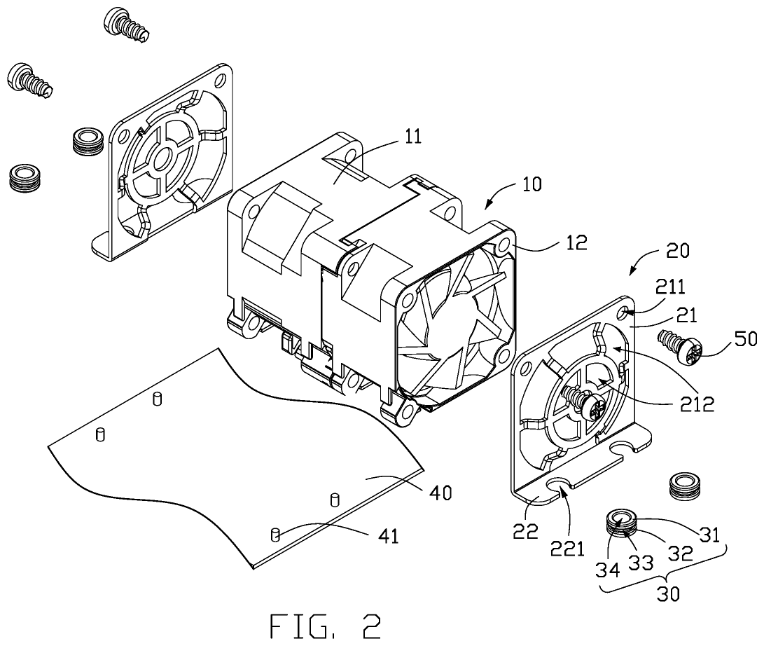

As shown in FIG. 2, the fan fixing structure 100 includes a fixing frame 20, at least one collar 30, and a mounting plate 40. The fixing frame 20 is configured to be mounted to the fan 10. The fixing frame 20 defines at least one latching hole 221. A quantity of the collar 30 is equal to a quantity of the latching hole 221. The at least one collar 30 is configured to be received in the corresponding at least one latching hole 221. The collar 30 defines a latching groove 33. The latching groove 33 is configured to receive an edge of the corresponding latching hole 221 to latch the fixing frame 20. The plate 40 includes at least one positioning post 41 configured to protrude through the at least one collar 30 to mount the fan 10 to the mounting plate 40. A quantity of the at least one positioning post 41 is equal to the quantity of the at least one collar 30.

The fan 10 includes a housing 11. In one embodiment, the housing 11 is substantially a rectangular parallelepiped. The fan 10 includes fan blades (not shown) at two ends of the housing 11 to be connected to a driving mechanism (not shown) received in the housing 11. At least one installation portion 12 is located on an end surface of the housing 11, and the fixing frame 20 is fixed to the at least one installation portion 12 by a fastener 50 to fix the fixing frame 20 to the fan 10. In one embodiment, the fastener 50 is a screw, but is not limited thereto. In other embodiments, the fan 10 can be other shapes, such as cylindrical, and the fan 10 can be connected to the fixing frame 20 by other means.

As shown in FIG. 2, the fixing frame 20 includes a first fixing plate 21 and a second fixing plate 22. The first fixing plate 21 is coupled substantially perpendicularly to the second fixing plate 22. The second fixing plate 22 extends away from the fan 10 when the fixing frame 20 is mounted to the fan 10. In other embodiments, the first fixing plate 21 and the second fixing plate 22 may be detachably coupled or integrally formed.

A shape of the first fixing plate 21 is substantially the same as a shape of the end surface of the housing 11, so that the first fixing plate 21 can be attached to the end surface of the housing 11. The first fixing plate 21 defines at least one mounting hole 211 corresponding in position to the at least one installation portion 12, and the fastener 50 passes through the mounting hole 211 to the installation portion 12 to mount the fixing frame 20 to the fan 10. The first fixing plate 21 further defines at least one through hole 212. In one embodiment, the first fixing plate 21 defines a plurality of through holes 212. The plurality of through holes 212 may have different shapes. In one embodiment, a plurality of pairs of through holes 212 having different shapes is defined in the first fixing plate 21, and the pairs of through holes 212 of the same shape are symmetrical about a center of the first fixing plate 21. Wind energy output by the fan 10 is transmitted through the through holes 212 to an electronic component to dissipate heat.

A first longitudinal side of the second fixing plate 22 is coupled to the first fixing plate 21, and the second fixing plate 22 extends a predetermined distance away from the fan 10. The latching hole 221 is defined in the second fixing plate 22, and the latching hole 221 is open on a second longitudinal side of the second fixing plate 22 opposite the first longitudinal side.

The collar 30 is substantially a hollow annular structure and includes a first abutting portion 31 and a second abutting portion 32. The latching groove 33 is defined between the first abutting portion 31 and the second abutting portion 32. The collar 30 is fastened to the second fixing plate 22 by the latching groove 33 engaging with an edge of the second fixing plate 22, and the first abutting portion 31 and the second abutting portion 32 respectively abut opposite surfaces of the second fixing plate 22.

In one embodiment, the mounting plate 40 includes a plurality of positioning posts 41. A position of the positioning posts 41 corresponds to a position of the latching holes 221.

In one embodiment, the collar 30 is made of rubber, and the positioning post 41 is substantially cylindrical. The collar 30 defines a positioning hole 34. A diameter of the positioning post 41 is larger than a diameter of the positioning hole 34. When the positioning post 41 protrudes into the positioning hole 34, the positioning hole 34 expands to sleeve the collar 30 on the positioning post 41, so that the fan 10 is more stably mounted on the mounting plate 40. In other embodiments, the collar 30 can be made of other materials having equivalent effects.

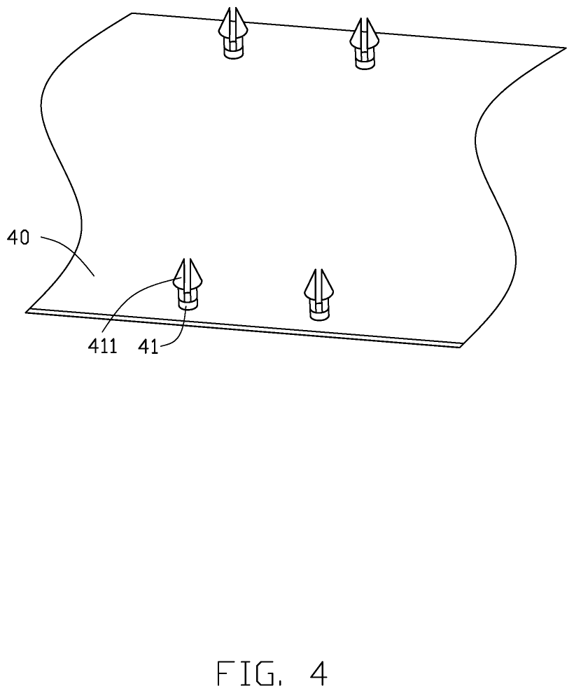

As shown in FIG. 4, in another embodiment, the positioning post 41 includes a barbed tip 411. When the fan 10 is mounted on the mounting plate 40, the barbed tip 411 resists against a surface of the second fixing plate 22 to prevent the fan 10 from moving in a direction perpendicular to a surface of the mounting plate 40.

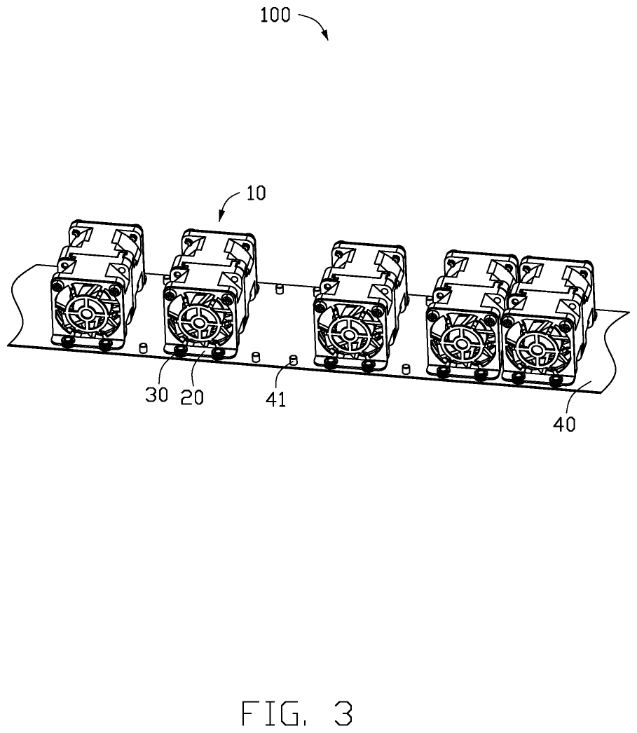

As shown in FIG. 3, in one embodiment, a plurality of fans 10 are mounted in a row on the mounting board 40. Each fan 10 includes two fixing frames 20 located at opposite ends of the fan 10. Each second fixing plate 22 defines two latching holes 221, and one collar 30 is received in each latching hole 221. The positioning posts 41 are evenly spaced along a longitudinal direction of the mounting plate 40 on two longitudinal sides of the mounting plate 40, and the positioning posts 41 are symmetrically located about a longitudinal axis of the mounting plate 40. Each of the plurality of fans 10 can be mounted on any two adjacent positioning posts 41. Thus, the fans 10 can be spaced apart at different distances on the mounting plate 40.

In other embodiments, the plurality of fans 10 can be mounted to the mounting plate 40 by one fixing frame 20, a quantity of the latching holes 221 defined in the second fixing plate 22 can be changed, and a spacing between adjacent positioning posts 41 can be changed according to actual needs.

The fans 10 are mounted on the mounting plate 40 by engagement of the collars 30 and the positioning posts 41. The fans 10 can be mounted in different positions according to positions of electronic components in the chassis. Thus, a structure of the fan fixing structure 100 is simple and convenient to use.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A fan fixing structure comprising:
a mounting plate;
a fixing frame mounted to a fan; and
a collar; wherein:
the fixing frame defines a latching hole;
the collar is received in the latching hole;
the collar defines a latching slot;
an edge of the fixing frame is latched in the latching slot;
the mounting plate comprises a positioning post configured to protrude through the collar; and
the fixing frame mounts the fan to the mounting plate.

2. The fan fixing structure of claim 1, wherein:
the fixing frame comprises a first fixing plate and a second fixing plate coupled to the first fixing plate;
the first fixing plate is perpendicularly coupled to the second fixing plate; and
the second fixing plate extends away from the fan when the fixing frame is mounted to the fan.

3. The fan fixing structure of claim 2, wherein:
the first fixing plate is mounted to the fan and defines a through hole; and
wind energy output by the fan is transmitted through the through hole.

4. The fan fixing structure of claim 3, wherein:
the latching hole is defined in the second fixing plate.

5. The fan fixing structure of claim 4, wherein:
the collar is made of rubber.

6. The fan fixing structure of claim 5, wherein:
the positioning post is cylindrical;
a diameter of the positioning post is larger than a diameter of the positioning hole; and
when the positioning post protrudes into the positioning hole, the positioning hole expands to sleeve the collar on the positioning post.

7. The fan fixing structure of claim 5, wherein:
the positioning post comprises a barbed tip; and
when the fan is mounted on the mounting plate, the barbed tip resists against a surface of the second fixing plate.

8. A fan fixing structure for fixing a plurality of fans in a chassis, the fan fixing structure comprising:
a mounting plate comprising a plurality of positioning posts;
a plurality of fixing frames mounted to the plurality of fans; and
a plurality of collars; wherein:
each fixing frame defines at least one latching hole;
each of the at least one latching hole is configured to receive a corresponding one of the plurality of collars;
each of the plurality of collars defines a latching slot for latching an edge of the fixing frame in the latching hole;
each positioning post is configured to protrude through a corresponding one of the plurality of collars; and
the fixing frames mount the fans to the mounting plate.

9. The fan fixing structure of claim 8, wherein:
the fixing frame comprises a first fixing plate and a second fixing plate coupled to the first fixing plate;
the first fixing plate is perpendicularly coupled to the second fixing plate; and
the second fixing plate extends away from the fan when the fixing frame is mounted to the fan.

10. The fan fixing structure of claim 9, wherein:
the first fixing plate is mounted to the fan and defines a through hole; and
wind energy output by the fan is transmitted through the through hole.

11. The fan fixing structure of claim 10, wherein:
the latching hole is defined in the second fixing plate.

12. The fan fixing structure of claim 11, wherein:
the collar is made of rubber.

13. The fan fixing structure of claim 12, wherein:
the positioning post is cylindrical;
a diameter of the positioning post is larger than a diameter of the positioning hole; and
when the positioning post protrudes into the positioning hole, the positioning hole expands to sleeve the collar on the positioning post.

14. The fan fixing structure of claim 13, wherein:
the positioning post comprises a barbed tip; and
when the fan is mounted on the mounting plate, the barbed tip resists against a surface of the second fixing plate.
